(19) United States
(12) Patent Application Publication
(10) Pub. No.: US 2025/0362464 A1
(43) Pub. Date: Nov. 27, 2025

(54) HIGH OUTPUT POWER PHOTONIC INTEGRATED CIRCUITS

(71) Applicants: Tin Komljenovic, Goleta, CA (US); Minh Tran, Goleta, CA (US); Chong Zhang, Santa Barbara, CA (US)

(72) Inventors: Tin Komljenovic, Goleta, CA (US); Minh Tran, Goleta, CA (US); Chong Zhang, Santa Barbara, CA (US)

(21) Appl. No.: 18/675,037

(22) Filed: May 27, 2024

(51) Int. Cl. G02B 6/42

(52) U.S. Cl. CPC G02B 6/4267; G02B 6/4207; G02B 6/4286; G02B 6/4295; G02B 6/4296

(57) ABSTRACT

A device has first, second, third and fourth elements, realized in combination as a photonic integrated circuit fabricated on a common substrate. The first has a first interface and a second interface of larger cross-section than the first and supports a first optical mode. The second element at least partly butt-coupled to the first interface at a first butt-coupled interface, has a first intermediate waveguide structure supporting a first intermediate optical mode. The third element at least partly butt-coupled to the second interface at a second butt-coupled interface, has an output facet and a second intermediate waveguide structure supporting a second intermediate optical mode. The fourth element has a first passive waveguide structure supporting a second optical mode. At least one of the second and fourth elements has a tapered waveguide structure facilitating efficient adiabatic transformation between the second optical mode and the first intermediate optical mode.

### FIELD OF THE INVENTION

The present invention relates to photonic integrated circuits. More specifically, certain embodiments of the invention relate to improved performance of heterogeneously integrated lasers and active components.

### BACKGROUND OF THE INVENTION

A photonic integrated circuit (PIC) or integrated optical circuit is a device that integrates multiple photonic functions and as such is analogous to an electronic integrated circuit. The major difference between the two is that a photonic integrated circuit provides functions for information signals imposed on optical carrier waves. A photonic integrated circuit can also generate light with advanced properties in one chip. The material platform most commercially utilized for photonic integrated circuits is indium phosphide (InP), which allows for the integration of various optically active and passive functions on the same chip. Although many current PICs are realized in InP platforms, there has been significant research in the past decade in using silicon rather than InP for the realization of PICs, due to some superior characteristics as well as superior processing capabilities for the former material, that leverage the investment already made for electronic integrated circuits.

The biggest drawback in using silicon for PICs is that it is an indirect bandgap material which makes it hard to provide electrically pumped sources. This problem is generally solved by assembling PICs comprising two or more chips made from dissimilar materials in separate processes. Such an approach is challenging due to a need for very fine alignment, which increases packaging costs and introduces scaling limitations. Another approach to solving the bandgap problem is to bond two dissimilar materials and process them together, removing the need for precise alignment during the bonding of larger pieces or complete wafers of the dissimilar materials, and allowing for mass fabrication. In this disclosure, we use the term “hybrid” to describe the first approach that includes precise assembly of separately processed parts, and we use the term “heterogeneous” to describe the latter approach of bonding two materials and then processing the bonded result to define the waveguides and other components of interest.

To transfer the optical signal between dissimilar materials, the heterogeneous approach historically utilized tapers whose dimensions are gradually reduced until the effective mode refractive indexes of two or more materials match and there is efficient power transfer. This approach generally works well when materials have small difference in refractive indexes as is the case with silicon and InP. In cases where there is a larger difference in effective indexes, such as between e.g. SiN and GaAs or InP, the requirements on taper tip dimensions become prohibitive limiting efficient power transfer.

Recently, a new class of heterogeneous PICs has been developed as described in e.g. U.S. Pat. No. 11,209,592 B2 and US patent application 17,732,348 in which integration of optically dissimilar materials is facilitated without using prohibitively narrow tapers. The approach utilizes butt-coupling assisted optical coupling between materials with large refractive index difference and generally has at least one etched facet as a part of the laser structure. Such PICs have demonstrated very good performance, especially in terms of laser noise (both frequency and amplitude)—primarily leveraging the low losses in the passive/waveguide material. At the same time, output powers of such lasers are generally limited to below 30 milliwatts (mW), very rarely as high as 100 mW, due to the resulting high intensity of the optical mode in the quantum well region as the mode area is typically smaller (to support efficient coupling to low-loss passive/waveguide material). Such high intensities can result in catastrophic optical mirror damage (COMD) if such lasers are operated at the high end of the output power. Many applications require higher powered lasers, exceeding 100 mW, and approaching or even exceeding 1 watt (W).

The present invention is directed towards heterogeneous lasers and PICs supporting high power operations by optimizing the mode-size at the output of the laser/PIC. In particular, embodiments described below are concerned with the detailed design of the PIC output facet region for creation of high-performance, high-power heterogeneous lasers and other PICs utilizing dissimilar materials.

### BRIEF DESCRIPTION OF THE DRAWINGS

FIG. 1 shows a device according to one embodiment of the present invention, shown in cross-sectional top-down view and in cross-section view.

FIG. 2 shows two top-down views of devices according to some embodiments of the present invention.

FIG. 3 shows a top-down view of a device according to some embodiments of the present invention.

FIG. 4 shows multiple end-on cross-sectional views illustrating exemplary fabrication process flow of a device according to some embodiments of the present invention.

### DETAILED DESCRIPTION

Described herein are embodiments of a platform for realization of heterogeneously integrated photonic integrated circuits using dissimilar materials where optical coupling is improved by use of mode conversion and a butt-coupling scheme. More specifically, certain embodiments of the invention relate to improved high-power performance of heterogeneously integrated lasers and PICs.

In the following detailed description, reference is made to the accompanying drawings which form a part hereof, wherein like numerals designate like parts throughout, and in which are shown by way of illustration embodiments in which the subject matter of the present disclosure may be practiced. It is to be understood that other embodiments may be utilized, and structural or logical changes may be made without departing from the scope of the present disclosure. Therefore, the following detailed description is not to be taken in a limiting sense, and the scope of embodiments is defined by the appended claims and their equivalents.

The description may use perspective-based descriptions such as top/bottom, in/out, over/under, and the like. Such descriptions are merely used to facilitate the discussion and are not intended to restrict the application of embodiments described herein to any particular orientation. The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

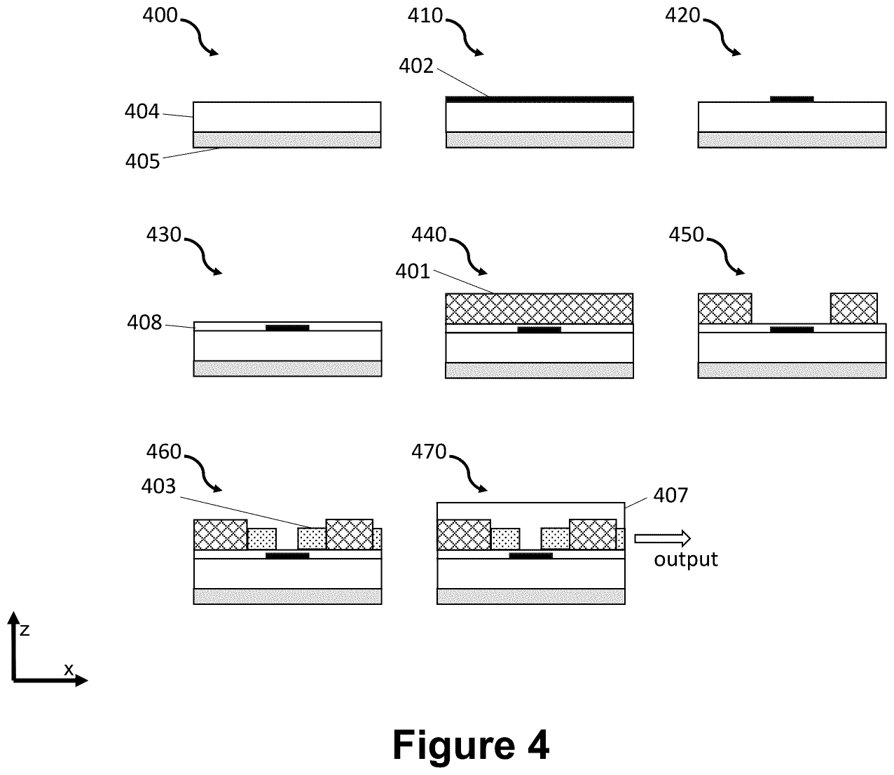

The term “coupled with,” along with its derivatives, may be used herein. “Coupled” may mean one or more of the following. “Coupled” may mean that two or more elements are in direct physical, electrical, or optical contact. However, “coupled” may also mean that two or more elements indirectly contact each other, but yet still cooperate or interact with each other, and may mean that one or more other elements are coupled or connected between the elements that are said to be coupled with each other. The term “directly coupled” means that two or more elements are in direct contact in at least part of their surfaces. The term “butt-coupled” is used herein in its normal sense of meaning an “end-on” or axial coupling, where there is minimal or zero axial offset between the elements in question. The axial offset may be, for example, slightly greater than zero in cases where a thin intervening layer of some sort is formed between the elements, such as e.g. thin coating layer typically used to provide high-reflectivity or anti-reflectivity functionality. It should be noted that the axes of two waveguide structures or elements need not be colinear for them to be accurately described as being butt-coupled. In other words, the interface between the elements need not be perpendicular to either axis. FIG. 4 embodiments discussed below are exemplary of such possibilities. No adiabatic transformation occurs between butt-coupled structures.

The term “active device”, “active structure” or otherwise “active” element, region, part, or component may be used herein. A device or a part of a device called active is capable of light generation, amplification, modulation and/or detection using electrical contacts. This is in contrast to what we mean by a “passive device” or component whose principal function is to confine and guide light, and/or provide splitting, combining, filtering and/or other functionalities that are commonly associated with the term “passive”. Some passive components can provide functions overlapping with active component functionality, such as e.g. phase tuning implemented using thermal effects or similar that can provide modulation. No absolute distinction should be assumed between “active” and “passive” based purely on material composition or component structure. A silicon component or device, for example, may be considered active under certain conditions of modulation, or detection of low wavelength radiation, but passive in most other situations.

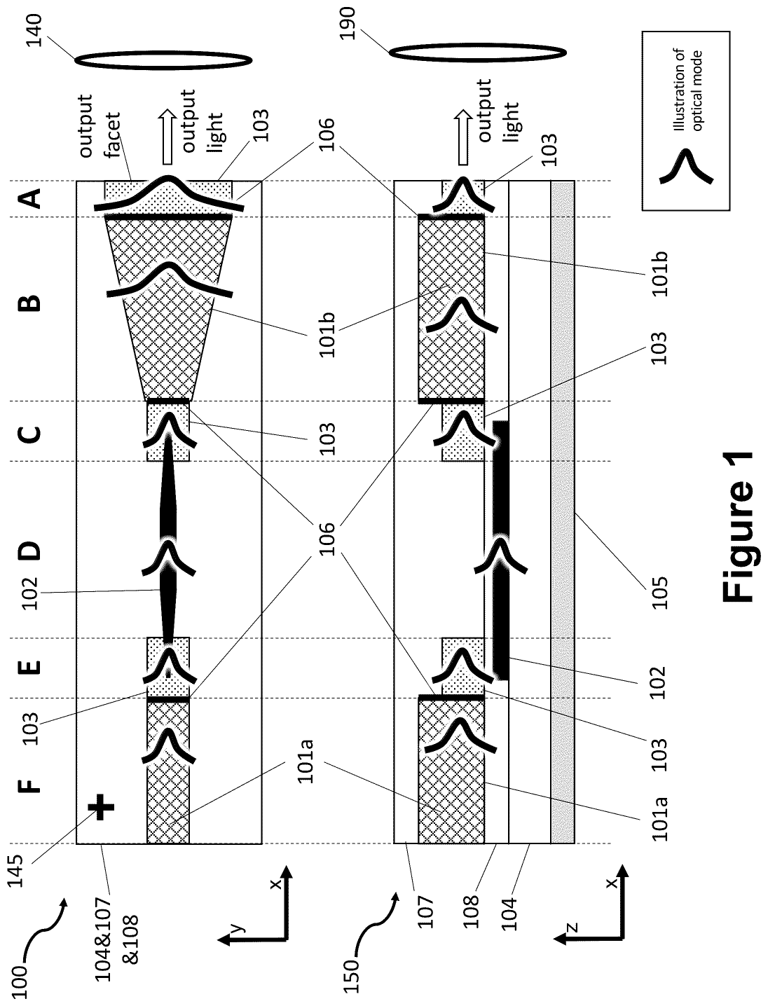

FIG. 1 shows one embodiment of the present invention shown in cross-sectional top-down view 100 and in cross-section view 150.

The shown embodiment includes a substrate 105. The substrate 105 can be any suitable substrate for semiconductor and dielectric processing, such as Si, InP, GaAs, quartz, sapphire, glass, GaN, silicon-on-insulator or other materials known in the art. Layer 104, on top of substrate 105, provides optical cladding for layer 102 (described below), if necessary to form an optical waveguide. In some embodiments, layer 104 comprises SiO2 and/or SiNOₓ. In some embodiments, layer 104 is omitted and substrate 105 itself serves as a cladding, e.g. in the case where layer 105 is a lower refractive index material such as quartz, sapphire, glass, etc.

Layer 102 provides passive waveguide functionality such as low-propagation loss, wide-band transparency, high intensity handling, phase shifting by temperature, combining, splitting, filtering, non-linear generation and/or others as is known in the art. By combining passive waveguides with gain regions (as described below), high-performance lasers can be realized utilizing low-losses to make e.g. Vernier-based lasers, distributed Bragg reflector lasers, or similar sources providing narrow-linewidths and/or wide tunability such as described by Minh A. Tran et al¹,.

The refractive index of layer 102 is higher than the refractive index of layer 104 if present, or, if layer 104 is not present, the refractive index of layer 102 is higher than the refractive index of substrate 105. In one embodiment, the material of layer 102 may include, but is not limited to, one or more of SiN, SiNOₓ, TiO₂, Ta₂O₅, (doped) SiO₂, LiNbO₃ and AlN.

Layer 108, whose refractive index is lower than the refractive index of layer 102, serves to planarize the patterned surface of layer 102. The planarization may be controlled to leave a layer of desired, typically very low, thickness of layer 108 on top of the layer 102 (as shown in view 150), or to remove all “108” material above the level of the top surface of the layer 102 (not shown). In the cases where part of layer 108 is left on top of layer 102, the target thicknesses on top of layer 102 are in the range of few nm to several hundreds of nm, with actual thickness, due to planarization process non-uniformities, being between ¹ Minh A. Tran, Duanni Huang, John E. Bowers; Tutorial on narrow linewidth tunable semiconductor lasers using Si/III-V heterogeneous integration. APL Photonics 1 Nov. 2019; 4 (11): 111101. https://doi.org/10.1063/1.5124254 zero and several hundreds of nanometers larger or smaller than the target thickness. In yet another embodiment (not shown), there is no planarization layer 108 filling in the etched regions of layer 102. In this embodiment there would be depressions or pockets where layer 102 was etched. In the shown embodiment, layer 102 is not present below layer 101a/101b (described below), in other embodiments layer 102 (patterned or un-patterned) is present below at least one of layers 101a/101b.

In some embodiments, layers 101a and 101b are attached to the planarized top surface comprising layers 102 and/or 108. In other embodiments there could be additional thin layers between layer 102/108 and 101a/101b to facilitate higher yield attachment. The attachment can utilize direct molecular bonding (with or without supporting thin layers) or can use additional materials to facilitate bonding such as e.g., metal layers or polymer films as is known in the art. Layers 101a/101b make up what is commonly called an active device, component or region and may be multilayered and/or patterned to provide optical and electrical confinement as is known in the art of active semiconductor devices/components such as optical sources, modulators, amplifiers and detectors. Layers 101a/101b, in some embodiments, comprise at least one of GaAs, InP and GaN, and their related ternary and quaternary compounds.

In some embodiments, layers 101a and 101b are identical in composition and can be bonded to an underlying surface in a single step; one example would be layer 101a providing laser functionality and layer 101b providing booster amplifier functionality in which both can comprise a gain optimized structure including quantum wells or quantum dots. In other embodiments, layers 101a and 101b are compositionally different, and the bonding process can include two steps. In such embodiments, they can have significantly different functions and structures, e.g. layer 101a can provide modulator capability, or high-performance photodetector capability, while layer 101b provides booster amplifier capability.

Efficient coupling between waveguides realized in layers 101a/101b and waveguides realized in layer 102 is facilitated by layer 103, and, in cases where layer 106 is present, by layer 106. Optional layer 106 is a coating that primarily serves as either an anti-reflective or a highly reflective coating at the interface between layer 101 and layer 103. Layer 103 is typically deposited on top of a planarized surface comprising layers 102 and/or 108, depending on the nature of planarization as described above in relation to layer 108. Layer 103 has a lower refractive index than layer 102, and a higher refractive index than those layers providing cladding functionality (104, 108 and/or 107 which is described below). In this illustrative embodiment, the mode progression from left to right in FIG. 1 goes as follows. Layer 103 serves as an intermediate waveguide core that in some embodiments accepts the profile of an optical mode supported by the waveguide for which layer 101a in region “F” provides the core, captures it efficiently and transforms it into a mode with a second profile shown in region “E”, and then gradually transforms that second-profile mode to a mode with a third profile shown in region “D”, supported by a waveguide for which layer 102 provides the core. This third-profile mode can then be gradually transformed back to a mode with the fourth profile, shown in region “C”, supported by a waveguide for which layer 103 provides the core, before transforming it to an optical mode with a fifth profile, shown in region “B”, supported by a waveguide for which layer 101b provides the core. Finally, the mode is transferred to region “A”, supported by a waveguide for which layer 103 provides the core before being coupled via an output facet to either free space, a fiber (not shown), and/or another apparatus (not shown). Layer 103 in region “A” can be optional, e.g. in some embodiments, region “B” can be coupled via a facet (not shown) to either free space, a fiber, and/or another apparatus.

There are two types of transitions in the above flow. The transition from regions “F” to “E”, “C” to “B” and “B” to “A” utilize butt-coupling in which coupling efficiency is maximized by optimizing the mode shapes at the butt-coupled interface for maximum overlap, and optionally utilizing coatings 106. Coatings can be anti-reflective, to reduce the reflection at the interface, can be highly reflective to increase reflectivity at the interface if one wants to realize mirrors, or they can provide other functionality including passivation of the surface. In these butt-coupling situations, the waveguides are not stacked one above the other in a vertical dimension (z-axis in view 150). The transitions from regions “E” to “D”, and “D” to “C” utilize evanescent coupling in which the waveguides are partially stacked, one above the other (along the z-axis in view 150), and their dimensions are optimized to support evanescent coupling using tapers in at least one of the corresponding waveguides (whose waveguide cores defined in layers 102 and/or 103).

The refractive index and dimensions of layer 103 can be engineered to facilitate efficient butt-coupling of respective mode profiles to active regions 101a/101b and to efficiently transform the modes by taking advantage of tapered structures made in layer 102 and/or 103. The requirements on taper dimensions are easy to satisfy as the refractive index difference of layers 102 and 103 is typically small (smaller for example than the refractive index difference between layer 101 and 102) so phase matching is simplified and does not require prohibitively narrow taper tips.

Layer 107 is the upper cladding layer and can comprise polymer, SiO₂, SiN, SiNOₓ etc. In some embodiments (not shown), layer 107 cladding functionality can be provided with multiple depositions and/or multiple materials to e.g. manage stress or provide additional functionality (e.g. surface passivation for layers 101a/101b).

Regions “B” and “A” taken together can be considered to be a “high-power” region, where “B” provides optical amplification functionality and, in some embodiments, utilizes tapers to enlarge the mode laterally, along the y-axis. The total power supported by the waveguide structure (assuming that peak intensity is limited by material composition and facet quality) increases in proportion to the increase in mode size. The guiding and spreading of the mode along the y-axis in region “B” can utilize etched or partially-etched waveguides, but can also utilize doping or other gain-guiding mechanisms that have been shown to increase the peak output powers, as these latter approaches reduce the interaction of the optical mode with etched sidewalls in the gain material. In some embodiments the mode area increases by more than 2× as it propagates in region B from left to right interface.

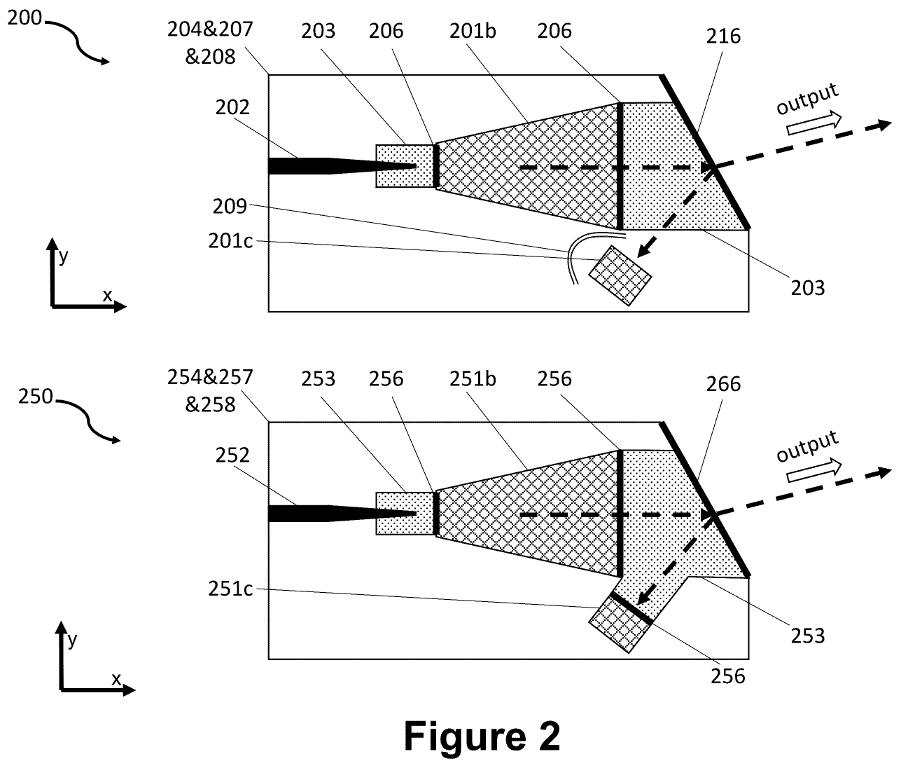

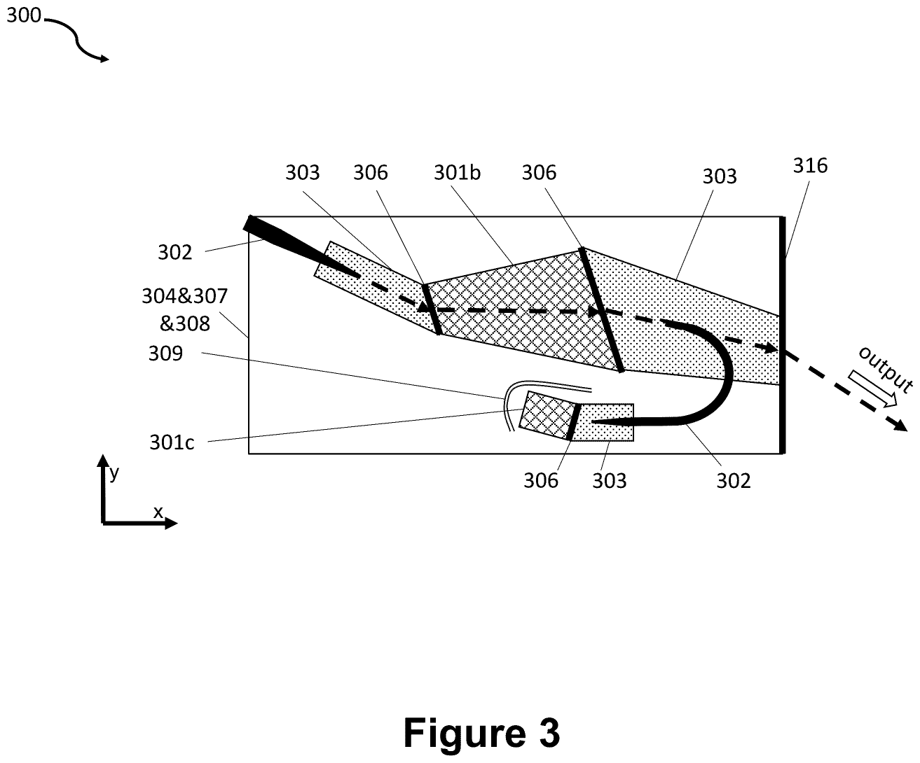

The transition between regions “B” and “A” utilizes butt-coupling, and the waveguide formed in region “A” can be used to further shape the beam as described with the help of FIGS. 2 and 3. In cases where there is a large aspect ratio between the horizontal (y-axis) and vertical (z-axis) dimensions of the facet at the right side of region “A” (as suggested in FIG. 1), an optical lens 140 can be utilized to accept the beam emerging from region A and deliver an output beam that is more circular, or shaped in other ways that are optimal for a given application.

Active components (101a/101b) also have electrical contacts (not shown). to provide electrical signals to control the component, e.g. to inject carriers in the case of optical semiconductor amplifier Common alignment mark(s), one example of which is shown in view 100 as alignment mark 145, are used to align process steps, as will be described in more detail below with reference to FIG. 4.

FIG. 2 shows two embodiments of the present invention shown in cross-sectional top-down views 200 and 250. While the embodiment shown in FIG. 1 enables significant increase of the output power by leveraging increased mode size at the output, in some cases it would be beneficial to also have a photodetector capable of measuring that output power. Such functionality could be used to provide feedback to the gain element and provide output power control, or even to reduce the intensity noise of the on-chip lasers using a fast feedback loop. Views 200 and 250 show two embodiments that enable monitoring the output power of photonic integrated circuits which provide high output power using the mode spreading techniques described above in relation to FIG. 1.

View 200 shows an embodiment of the present invention in which a photodetector 201c is suitably positioned and oriented to receive light reflected back from the output facet, this light being small relative to the light transmitted from the facet as the output beam. Photodetector 201c can utilize active layers identical to those of the optical amplifier 201. Alternatively, 201c can utilize another bonded material that has different semiconductor layers, optimized for photodetector functionality. Functional layers 202 to 208, unless explicitly defined differently, correspond to functional layers 102 to 108 as described in relation to FIG. 1. In the shown embodiment, the output facet is angled relative to the waveguide axis (horizontal in the view shown) to minimize the back reflection into the waveguides. The transmission of an amplified optical signal to form the output beam can be further optimized using coating 216 that can comprise one or more thin-film layers optimized to enhance the transmission, and consequently further reduce the reflection. But even with an optimized facet angle and/or the use of coating 216, there is a small part of the incident signal that is reflected at the facet, as illustrated by the arrow pointing down and to the left. The magnitude of the reflected power is proportional to the magnitude of the power reaching the facet, and to the magnitude of the power transmitted through the facet to form an output beam. The angle of the facet, and the position of photodetector 201c can be optimized such that a significant part of the reflected signal is incident on photodetector 201c and can be used to monitor the power reaching the facet. In some embodiments, the reflected fraction can be as small as −40 dB, or even less, but this can still result in μW of power reaching the photodetector when output powers, illustrated by the arrows pointing up and to the right are larger than 10 mW. In some embodiments, to improve the signal to noise of the photodetector, light blocking structures 209 can be introduced. In some of these embodiments, the light blocking structures can comprise metal, III-V semiconductors and/or periodic structures that are optimized to minimize the amount of scattered light reaching the photodetector directly from the optical amplifier 201b rather than after being reflected from the facet. Such structures may also reduce scattered light reaching the photodetector from any other on-chip sources. The impact of scattered light on the photodetector can be further reduced by scatter prevention techniques, such as the use of opaque epoxies, during the packaging of the laser/PIC.

View 250 shows another embodiment of the present invention in which a photodetector 251c is suitably positioned and oriented to receive light reflected back from the output facet, this light being small relative to the light transmitted through the facet as an output beam. Functional layers 252 to 266, unless explicitly defined differently, correspond to functional layers 202 to 216 as described in relation to view 200 of FIG. 2. A difference between embodiments shown in view 200 and view 250 is shown on the right side of the figure at the facet, where element 203 in view 200 is replaced by element 253 in view 250, and where element 253 includes a waveguide like structure extending up to and coupled to photodetector 251c, optionally comprising optical coating layer 256. This additional waveguide like structure can increase the amount of reflected light that is coupled to the photodetector, as the reflection/refraction effects at the boundary of layers 203 and 204&207&208 encountered by light reflected from the facet are effectively eliminated for the light that is reflected at the output facet.

FIG. 3 shows an embodiment of the present invention shown in cross-sectional top-down view 300. The embodiment shown in FIG. 3 utilized multiple angled facets to control the reflection at butt-coupled interfaces of the PIC. This can be applied to any other embodiment described earlier with the help of FIGS. 1 and 2. Functional layers 302 to 316, unless explicitly defined differently, correspond to functional layers 202 to 216 as described in relation to view 200 of FIG. 2. In contrast to embodiments described in FIG. 2, the embodiment shown in FIG. 3 utilizes an additional waveguide in layer 302 to couple a small portion of the light entering one intermediate waveguide in layer 303 from 301b to photodetector 301c. The coupling occurs in a sequence of steps, first utilizing evanescent coupling from 303 to 302, next utilizing evanescent coupling from 302 to another intermediate waveguide in 303, and finally utilizing butt-coupling from 303 to 301c. The waveguide realized in layer 302 is configured to tap a very small portion (typically less than 1%) of the light outputted from gain region 301b into 303 and couple it to the photodetector to provide monitoring of the power output from the device, illustrated by the arrow pointing down and to the right. This tapping is performed by forming a vertical directional coupler (in the z-axis, perpendicular to the plane of the figure) to redirect that small portion of light from 303 down into 302

It is obvious to someone skilled in the art the multiple combinations of the approaches discussed above may be used, for example to combine angled butt-coupled interfaces and coating layers to control both on-chip reflection and reflection at the output facet. Similarly, various arrangements that couple at least part of the power reaching the output facet to a monitor photodetector using reflected signals and/or tap couplers can be envisioned.

FIG. 4 shows multiple end-on cross-sectional views illustrating an exemplary fabrication process flow for devices according to some embodiments of the present invention. The fabrication process starts in view 400 where a cladding 404 is deposited or grown onto, or transferred to, a suitable substrate 405. The process then proceeds to view 410 in which layer 402 is deposited, and then patterned in view 420 to define passive components. This patterning, in some embodiments, is also used to define common alignment marks (not visible in this cross-section, but see 145 as described in relation to FIG. 1) in layer 402 that are used for all subsequent processing steps. After this, the process can move to view 430 in which layer 408 is deposited and suitably planarized to prepare the top surface for the next step. In the embodiment shown, there is a thin layer of 408 on top of layer 402, while in other embodiments (not shown) layer 408 might be fully removed from the top surface of layer 402. After planarization, the process moves to view 440 where layer 401 is bonded on top of the planarized surface. In this shown embodiment, a single piece of layer 401 is bonded that can e.g. comprise both layers 101a and 101b as described in relation to FIG. 1. In other embodiments, multiple pieces of layer 401 can be bonded (not shown). In the following view 450, layer 401 is suitable patterned which can include one or more etches, metallization and/or passivation steps as is common in the art of making III-V active devices/components. This patterning utilizes the alignment marks defined in view 420 enabling very good alignment (typically better than 200 nm) between the active and passive components, while not requiring high precision during the bonding process. The process then moves to view 460 in which layer 403 is deposited and patterned (again using the alignment marks), before proceeding to view 470 in which top cladding 407 is deposited. This illustrates just some of the process steps that might be carried out to realize some embodiments of the present invention, and actual process steps might not be carried out in exactly the same order, may omit one or more of these steps, and/or might add additional steps such as etching vias, depositing contacts, pads, surface passivation, coating layers, etc.

It is to be understood that these illustrative embodiments teach just several examples of heterogeneously integrated lasers and active components optimized for high-power operation utilizing the present invention, and many similar arrangements can be envisioned. Furthermore, such lasers and active components can be combined with multiple other components to provide additional functionality or better performance such as various filtering elements, amplifiers, monitor photodiodes, modulators, single-frequency lasers, widely tunable lasers, broadband optical sources and/or other photonic components. Some embodiments can utilize multiple transitions between passive waveguides and active regions utilizing intermediate waveguides beyond the few discussed in detail herein.

Embodiments of the present invention offer many benefits. The integration platform enables scalable manufacturing of PICs made from multiple materials providing higher-performance and/or ability to operate in broadband wavelength range. Furthermore, the platform is capable of handling high output optical power, and can provide a way to monitor and control the output power via the use of monitor photodetectors.

This present invention utilizes a process flow which typically begins with wafer-bonding of a piece of compound semiconductor material on a carrier wafer with dielectric waveguides (as is described with the help of FIGS. 1 and 4) and subsequently continues with standard semiconductor fabrication processes as is known in the art. It enables an accurate definition of optical alignment between components typically via a photo lithography step, removing the need for precise physical alignment. The photo lithography-based alignment allows for scalable manufacturing using wafer scale techniques.

Embodiments of the optical devices described herein may be incorporated into various other devices and systems including, but not limited to, various computing and/or consumer electronic devices/appliances, communication systems, medical devices, timing devices, quantum devices, sensors and sensing systems.

It is to be understood that the disclosure teaches just few examples of the illustrative embodiment and that many variations of the invention can easily be devised by those skilled in the art after reading this disclosure and that the scope of the present invention is to be determined by the following claims.

1. A device comprising:
a first element, comprising a gain element supporting a first optical mode, the first element having a first interface and a second interface, the second interface having a larger cross-section than the first interface;
a second element, at least partly butt-coupled to the first interface of the first element at a first butt-coupled interface, the second element comprising a first intermediate waveguide structure supporting a first intermediate optical mode;
a third element, at least partly butt-coupled to the second interface of the first element at a second butt-coupled interface, the third element comprising an output facet and a second intermediate waveguide structure supporting a second intermediate optical mode; and
a fourth element, comprising a first passive waveguide structure supporting a second optical mode;
wherein at least one of the second and fourth elements has a tapered waveguide structure facilitating efficient adiabatic transformation between the second optical mode and the first intermediate optical mode; and
wherein first, second, third and fourth elements are realized in combination as a photonic integrated circuit fabricated on a common substrate.

2. The device of claim 1,
wherein at least one of the first and second butt-coupled interfaces and the output facet comprises a coating configured to reduce back-reflection.

3. The device of claim 1,
wherein at least one of the first and second butt-coupled interfaces is angled such as to reduce back-reflection.

4. The device of claim 1,
additionally comprising a fifth element comprising a photodetector fabricated on the common substrate;
wherein a portion of an optical signal passing through the second intermediate waveguide structure is coupled to the photodetector.

5. The device of claim 4,
wherein the output facet is angled relative to a direction perpendicular to an axis of travel of the optical signal incident on the optical facet such that back-reflection into the gain element is correspondingly reduced.

6. The device of claim 5,
wherein reflection occurring at the output facet after the optical signal passes through the second intermediate waveguide structure provides the portion of the optical signal that is coupled to the photodetector.

7. The device of claim 6,
wherein the second intermediate waveguide structure in the third element comprises a waveguide segment butt-coupled to the photodetector, improving coupling of reflected light between the output facet and the photodetector.

8. The device of claim 4, additionally comprising a sixth element comprising a second passive waveguide structure fabricated on the common substrate;
wherein tapping, by the second passive waveguide structure, of the optical signal passing through the second intermediate waveguide structure provides the portion of the optical signal that is coupled to the photodetector.

9. The device of claim 4,
additionally comprising a seventh element comprising a light blocking structure fabricated on the common substrate;
wherein the light blocking structure is configured to block at least a portion of scattered light that would otherwise be incident on the photodetector.

10. The device of claim 9,
wherein the light blocking structure comprises III-V elements.

11. The device of claim 9,
wherein the light blocking structure comprises metals.

12. The device of claim 4,
wherein the first passive waveguide structure comprises at least one of SiN, SiNOx, TiO2, Ta2O5, doped SiO2, LiNbO3 and AlN.

13. The device of claim 4,
wherein the gain element comprises at least one of GaAs, InP and GaN.
